(19) United States
(12) Patent Application Publication
(10) Pub. No.: US 2026/0169042 A1
(43) Pub. Date: Jun. 18, 2026

(54) Resistance Detection Method and Resistance Detection Circuit

(71) Applicant: Joulwatt Technology Co., Ltd., Hangzhou (CN)

(72) Inventor: Yang Cheng, Hangzhou (CN)

(21) Appl. No.: 19/414,243

(22) Filed: Dec. 9, 2025

(30) Foreign Application Priority Data
Dec. 16, 2024 (CN) 202411853504.8

(51) Int. Cl. G01R 27/16

(52) U.S. Cl. CPC G01R 27/16

(57) ABSTRACT

This application discloses a resistance detection method and a resistance detection circuit. A test voltage and a reference voltage are obtained, and one of them is set as a value-to-be-compared and the other one is set as a reference value with a fixed value. The test voltage is a voltage value obtained by applying a test current to a unit-under-test, and the reference voltage is a voltage value generated by a reference voltage supply circuit. The value-to-be-compared includes a first boundary value and a second boundary value. The first boundary value and the second boundary value are compared with the reference value respectively to obtain a first comparison result and a second comparison result. A resistance range of a resistance of the unit-under-test is calculated based on the first comparison result and the second comparison result.

### CROSS-REFERENCE TO RELATED APPLICATIONS

This patent application claims priority to China Patent Application No. 202411853504.8, filed on Dec. 16, 2024 and entitled “RESISTANCE DETECTION METHOD AND RESISTANCE DETECTION CIRCUIT,” which is hereby incorporated by reference herein as if reproduced in its entirety.

### TECHNICAL FIELD

The present disclosure relates generally to the field of electronic circuit technology, and in particular embodiments, to a resistance detection method and a resistance detection circuit.

### BACKGROUND

Power over Ethernet (POE) equipment, also known as remote power supply equipment, includes a power sourcing equipment (PSE) and powered device (PD).

FIG. 1 shows a schematic block diagram of a POE power supply system (also referred to as a POE system) according to the existing technology. As shown in FIG. 1, the Ethernet power supply system (POE power supply system) may include a PSE (not shown) and a PD. The PSE is connected to powered terminals of the PD through a network transformer and an Ethernet twisted pair cable 20. In FIG. 1, a circuit 10 of the powered side may include a rectifier circuit 5, a detection resistor 6, and a switching circuit 7, and other components. Typically, in a POE power supply system, the characteristic impedance of a PD powered side is an impedance network comprising a rectifier circuit diode and a characteristic resistor connected in series. When connecting a PSE and a PD, the PSE power supply chip needs to detect the characteristic impedance of the PD powered side. When detecting that the characteristic impedance reaches a protocol standard, the powered side is considered as a POE protocol compliant device, and power will be supplied to the powered side. Traditional PSE chips use a detection method that applies different voltage signals to terminals of the PD device and detects the corresponding current information of the terminals, or applies different current signals to the terminals of the PD device and detects the voltage information of the terminals, and calculate the value of the characteristic impedance using the formula R=ΔV/ΔI.

Since POE systems are high-voltage power supply systems, traditional technologies require the design of high-voltage-resistant circuits to apply voltage or current to the PD powered side, detect voltage and current information, sample voltage and current, and perform calculations. This necessitates the use of high-voltage operational amplifiers, high-voltage sampling circuits, ADCs, and computational circuits, which often consume significant circuit area, leading to high chip costs. Furthermore, the common resistance calculation method is relatively simple, has a limited applicability, and is inaccurate in resistance detection.

### SUMMARY

Technical advantages are generally achieved, by embodiments of this disclosure which describe a resistance detection method and a resistance detection circuit.

To address the aforementioned technical problems, this application provides a resistance detection method and a resistance detection circuit to solve the problems in the prior art.

According to one aspect of the present disclosure, a resistance detection method is provided for detecting the resistance value of a unit-under-test, wherein the resistance detection method includes: obtaining a test voltage and a reference voltage, setting one of the two as a value to be compared and the other one as a reference value with a fixed value, the value to be compared including a first boundary value and a second boundary value; comparing the first boundary value and the second boundary value with the reference value respectively to obtain a first comparison result and a second comparison result; calculating a resistance value range to which the resistance of the unit-under-test belongs based on the first comparison result and the second comparison result, wherein the test voltage is a voltage value obtained by applying a test current to the unit-under-test, and the reference voltage is a voltage value generated by a reference voltage supply circuit.

Optionally, the test voltage is the value to be compared, and the reference voltage is the reference value. Obtaining the test voltage and the reference voltage includes: setting a minimum resistance value and a maximum resistance value; obtaining an upper limit value and a lower limit value of the test current based on the minimum resistance value and the maximum resistance value, respectively; applying the upper limit value of the test current and the lower limit value of the test current to the resistor of the unit-under-test, respectively, to obtain the first boundary value and the second boundary value; and setting a resistance reference value, and obtaining the reference voltage with the fixed value based on the resistance reference value as the reference value.

Optionally, the test voltage is the reference value, and the reference voltage is the value to be compared. Obtaining the test voltage and the reference voltage includes: setting a minimum resistance value and a maximum resistance value; obtaining a lower limit value and an upper limit value of the reference voltage based on the minimum resistance value and the maximum resistance value, respectively; using the lower limit value and the upper limit value of the reference voltage as the first boundary value and the second boundary value, respectively; applying a set current reference value to the resistor of the unit-under-test to obtain the test voltage of a fixed value as the reference value.

Optionally, if the resistance range calculated based on the first comparison result and the second comparison result does not fall within a resistance range formed by the minimum resistance value and the maximum resistance value, the value to be compared is reset.

Optionally, the resistance detection method further includes: adjusting the first boundary value and the second boundary value stepwise according to the first comparison result, the second comparison result and a detection accuracy, to update the resistance range until the resistance range reaches the detection accuracy, wherein each stepwise adjustment of the first boundary value and the second boundary value reduces the range of values of a range bounded by the first boundary value and the second boundary value.

Optionally, adjusting the first boundary value and the second boundary value includes: adjusting the test current applied to the unit-under-test to adjust the first boundary value and the second boundary value, or adjusting the voltage value generated by the reference voltage supply circuit to adjust the first boundary value and the second boundary value.

Optionally, the test voltage is the value to be compared, the reference voltage is the reference value, and the first boundary value and the second boundary value are adjusted stepwise according to the first comparison result, the second comparison result, and the detection accuracy to update the resistance range until the resistance range reaches the detection accuracy includes: if each time the first comparison result is that the first boundary value is greater than the reference value, the upper limit value of the test current is decreased stepwise until the first boundary value is less than the reference value; if each time the second comparison result is that the second boundary value is less than the reference value, the lower limit value of the test current is increased stepwise until the second boundary value is greater than the reference value; if the resistance range obtained according to the first comparison result and the second comparison result reaches the detection accuracy, the adjustment of the first boundary value and the second boundary value is stopped.

Optionally, the test voltage is the reference value, the reference voltage is the value to be compared, and the first boundary value and the second boundary value are adjusted stepwise according to the first comparison result, the second comparison result, and the detection accuracy, to update the resistance range until the resistance range reaches the detection accuracy includes: if each time the first comparison result is that the first boundary value is less than the reference value, the lower limit value of the reference voltage is increased stepwise until the first boundary value is greater than the reference value; if each time the second comparison result is that the second boundary value is greater than the reference value, the upper limit value of the reference voltage is decreased stepwise until the second boundary value is less than the reference value; if the resistance range obtained according to the first comparison result and the second comparison result reaches the detection accuracy, the adjustment of the first boundary value and the second boundary value is stopped.

Optionally, the unit-under-test is a powered device. If the resistance range is within a resistance value range specified in a protocol, impedance of the powered device is determined to meet a protocol standard.

According to another aspect of the present disclosure, a resistance detection circuit is provided for detecting a resistance of a unit-under-test. The resistance detection circuit is connected to the unit-under-test, The resistance detection circuit includes: a test current supply unit for applying a test current to the unit-under-test to generate a test voltage; a test voltage acquire unit for obtaining a test voltage from two terminals of the unit-under-test; a comparison unit for obtaining a reference voltage generated by a reference voltage supply circuit, taking one of the test voltage and the reference voltage as a value to be compared, and the other one as a reference value with a fixed value, wherein the value to be compared includes a first boundary value and a second boundary value, and comparing the first boundary value and the second boundary value with the reference value respectively to obtain a first comparison result and a second comparison result; and a resistance control unit for calculating a resistance range to which the resistance of the unit-under-test belongs based on the first comparison result and the second comparison result.

Optionally, the resistance control unit further adjusts the first boundary value and the second boundary value stepwise according to the first comparison result, the second comparison result and a detection accuracy, to update the resistance range until the resistance range reaches the detection accuracy. Each stepwise adjustment of the first boundary value and the second boundary value reduces a range of values bounded by the first boundary value and the second boundary value.

Optionally, the resistance control unit adjusts the first boundary value and the second boundary value by adjusting the test current generated by the test current supply unit, or by adjusting the voltage value generated by the reference voltage supply circuit.

Optionally, the test voltage is the value to be compared, the reference voltage is the reference value, and the test current supply unit obtains an upper limit value and a lower limit value of the test current according to preset minimum resistance value and maximum resistance value, and applies the upper limit value of the test current and the lower limit value of the test current to the resistor of the unit-under-test, so as to obtain the first boundary value and the second boundary value respectively; and the reference voltage supply circuit obtains the reference voltage with a fixed value according to a preset resistance reference value as the reference value.

Optionally, the test voltage is the reference value, the reference voltage is the value to be compared, and the reference voltage supply circuit obtains a lower limit value and an upper limit value of the reference voltage according to preset minimum resistance value and maximum resistance value, and uses the lower limit value and the upper limit value of the reference voltage as the first boundary value and the second boundary value, respectively; the test current supply unit applies a set current reference value to the resistor of the unit-under-test to obtain the test voltage with a fixed value as the reference value.

Optionally, the comparison unit includes at least one comparator. When the comparison unit includes only a comparator, the comparator receives the first boundary value and the second boundary value in a time-division manner.

According to yet another aspect of the present disclosure, a resistance detection method for detecting a resistance of a unit-under-test is provided, which includes: obtaining a test voltage and a reference voltage, with one of the test voltage and the reference voltage set as a value-to-be-compared, and the other one set as a reference value with a fixed value, wherein the value-to-be-compared includes a first boundary value and a second boundary value; comparing the first boundary value and the second boundary value with the reference value, respectively, to obtain a first comparison result and a second comparison result; and determining a resistance range to which the resistance of the unit-under-test belongs based on the first comparison result and the second comparison result; wherein the test voltage is a value obtained by applying a test current to the unit-under-test, and the reference voltage is a value generated by a reference voltage supply circuit.

According to yet another aspect of the present disclosure, a resistance detection circuit is provided for detecting a resistance of a unit-under-test connected to the resistance detection circuit. The resistance detection circuit includes: a test current supply unit configured to apply a test current to the unit-under-test to generate a test voltage; a test voltage acquire unit configured to acquire the test voltage from two terminals of the unit-under-test; a comparison unit configured to: obtain a reference voltage generated by a reference voltage supply circuit, set one of the test voltage and the reference voltage as a value-to-be-compared, and the other one as a reference value with a fixed value, the value-to-be-compared including a first boundary value and a second boundary value, and compare the first boundary value and the second boundary value with the reference value respectively to obtain a first comparison result and a second comparison result; and a resistance control unit configured to calculate a resistance range to which the resistance of the unit-under-test belongs based on the first comparison result and the second comparison result.

According to yet another aspect of the present disclosure, a method is provided that includes: applying a current to a powered device to generate a voltage across the powered device; selecting one of the voltage and a reference voltage as a parameter-to-be-compared, and the other one as a reference with a fixed value, the parameter-to-be-compared having a first boundary value and a second boundary value; comparing the first boundary value and the second boundary value of the parameter-to-be-compared with the reference, to generate a first comparison result and a second comparison result; and detecting a range of a resistance of the powered device based on the first comparison result and a second comparison result.

The resistance detection method and resistance detection circuit provided by the present disclosure obtain the test voltage by applying a test current to the unit-under-test, and then obtain the reference voltage from a reference voltage supply circuit. One of the test voltage and the reference voltage is set as a variable value, and the other as a fixed value. The comparison unit compares two different variable values (the first boundary value and the second boundary value) with the same fixed value, and the resistance range is generated based on the comparison results. Therefore, by setting different reference voltages or test currents, resistance ranges with different accuracies can be obtained, achieving multi-range detection and high-precision testing of resistance values. The present disclosure is applicable to many scenarios, has a wide range, and provides a high accuracy in resistance detection. Correspondingly, the resistance detection circuit implementing the resistance detection method uses a comparison unit as its core circuit, has a simple circuit structure, occupies a small area, and significantly reduces cost. Furthermore, the comparison unit may at least use only one comparator, which operates in a time-division multiplexing manner, i.e., the comparator receives the first boundary value and the second boundary value in the time-division multiplexing manner for comparison separately. Therefore, the resistance detection circuit only needs one high-voltage comparator, avoiding the use of numerous high-voltage components, resulting in a simple circuit structure and providing high safety.

Further, based on the comparison results, the first second boundary value and the second boundary value may be adjusted stepwise, such that the first second boundary value and the second boundary value may continuously approach each other, and the resistance range measured may continuously decrease, gradually approaching the minimum range corresponding to a detection accuracy. In other words, by continuously performing adjustment stepwise, the detected resistance value reaches the minimum detection accuracy, thus improving the accuracy and reliability of resistance detection.

Furthermore, the resistance detection method and resistance detection circuit may be applied to impedance detection in PD devices. By switching different reference voltages or test currents, and using the comparison results of the comparison unit to determine whether the impedance of the PD powered side meets the protocol standard, resistance detection method and resistance detection circuit are fast, efficient, and highly accurate.

It should be noted that the above general description and the following detailed description are exemplary and explanatory only, and do not limit the present disclosure.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 shows a schematic block diagram of a POE power supply system according to existing technologies;

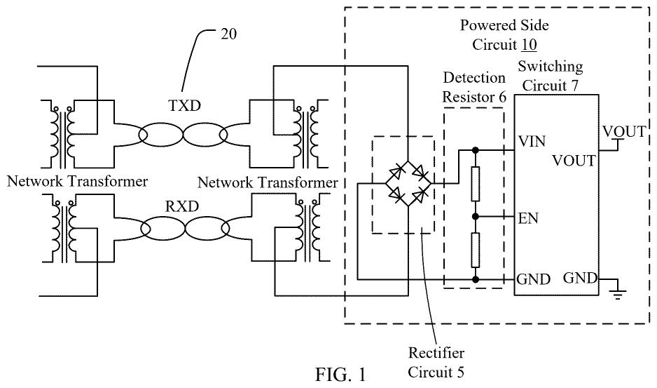

FIG. 2 shows a schematic block diagram of a resistance detection circuit according to an embodiment of the present disclosure;

FIG. 3 shows a schematic flowchart of a resistance detection method according to an embodiment of the present disclosure;

FIG. 4 shows a schematic circuit diagram of a resistance detection circuit according to a first embodiment of the present disclosure; and

FIG. 5 shows a schematic circuit diagram of a resistance detection circuit according to a second embodiment of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Furthermore, one or more features from one or more of the following described embodiments may be combined to create alternative embodiments not explicitly described, and features suitable for such combinations are understood to be within the scope of this disclosure. It is therefore intended that the appended claims encompass any such modifications or embodiments.

The present disclosure will be described with respect to embodiments in a specific context, namely a power over Ethernet (POE) power supply system. The disclosure may also be applied, however, to a variety of power supply systems and apparatuses where detection of resistance of a power supply receiver is performed in order for a power supply transmitter to supply power to the power supply receiver. Hereinafter, various embodiments will be explained in detail with reference to the accompanying drawings.

To facilitate understanding of the present disclosure, a more complete description will be given below with reference to the accompanying drawings. Embodiments of the present disclosure are shown in the drawings. However, the present disclosure may be implemented in various forms and is not limited to the embodiments described herein. Rather, these embodiments are provided to facilitate a thorough and complete understanding of the present disclosure.

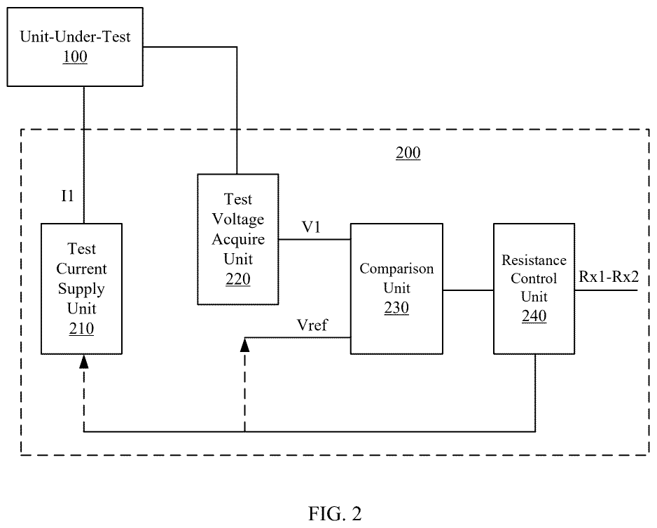

Embodiments of the present disclosure provide a resistance detection circuit, which may be configured to execute subsequent resistance detection methods to obtain the precise resistance range of a unit-under-test. It may be applied in a POE power supply system to detect the characteristic impedance of a PD. The resistance detection method and circuit of embodiments of the present disclosure are described in detail below with reference to FIG. 2-FIG. 4. The terms of “POE power supply system” and “POE system” are used interchangeably herein.

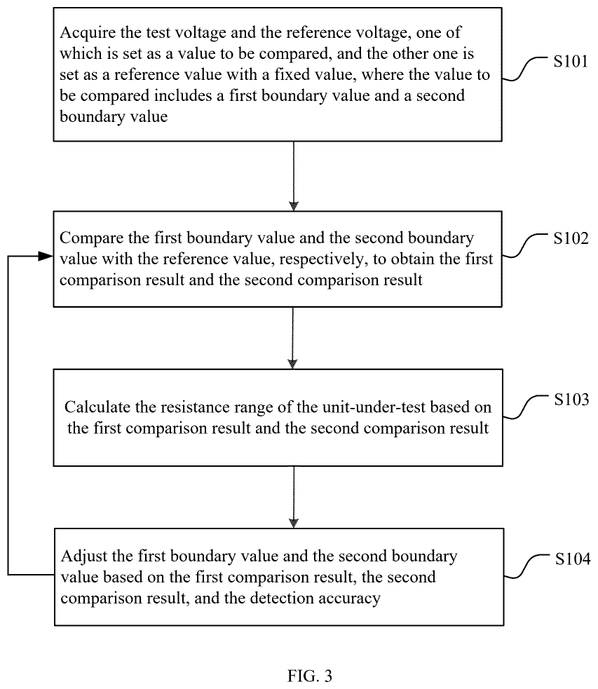

FIG. 2 is a schematic block diagram of a resistance detection circuit 200 according to an embodiment of the present disclosure. In this example, the resistance detection circuit 200 is provided for detecting the resistance value of a unit-under-test 100. The unit-under-test 100 may be any circuit whose resistance needs to be detected, and its characteristic resistance is represented by R. When applied in load impedance detection of a POE system, the unit-under-test 100 may be a powered device (PD) (or a power receiver), for example, in detection of the characteristic impedance value of an equivalent resistance of the PD. This resistance detection circuit 200 may be configured to perform the resistance detection method in the embodiment described in FIG. 3.

As shown in FIG. 2, the resistance detection circuit 200 of this embodiment includes a test current supply unit 210, a test voltage acquire unit 220, a comparison unit 230, and a resistance control unit 240. The test current supply unit 210 applies a test current I1 to the unit-under-test 100 to generate a test voltage V1 on the unit-under-test 100. The test voltage acquires unit 220 acquires the test voltage V1 from two terminals of the unit-under-test 100. The comparison unit 230 is configured to acquire a reference voltage Vref generated by a reference voltage supply circuit (not shown in the figure) and also to acquire the test voltage V1. One of the test voltage V1 and the reference voltage Vref is used as the value to be compared, and the other one is used as a reference value with a fixed value. The value to be compared includes a first boundary value and a second boundary value. The comparison unit 230 compares the first boundary value and the second boundary value with the reference value respectively to obtain a first comparison result and a second comparison result. The comparison unit 230 may include at least one comparator; that is, the comparison unit 230 may be provided with at least one comparator, and may also be provided with two or more comparators. When only one comparator is provided, the comparator receives the first boundary value and the second boundary value in a time-division multiplexing manner, and then compares them with the reference value respectively to obtain the first comparison result and the second comparison result. The resistance control unit 240 calculates a resistance value range Rx1-Rx2 to which the resistance of the unit-under-test 100 belongs, based on the first comparison result and the second comparison result. The first boundary value and the second boundary value form an range, and a resistance value range corresponding to the range is detected.

In one feasible embodiment, the test voltage V1 is the value to be compared, and the reference voltage Vref is the reference value. That is, the reference voltage Vref is a pre-set fixed value. For example, a reference voltage supply circuit may be configured to obtain a fixed reference voltage Vref based on a preset resistance reference value RT as the reference value. The test voltage V1 may take two values, corresponding to the first boundary value and the second boundary value, respectively. At this time, the test current supply unit 210 obtains a upper limit value and a lower limit value of the test current I1 based respectively on a minimum resistance value Rmin and a maximum resistance value Rmax that are preset. The upper limit value and the lower limit value of the test current I1 are applied to the resistor of the unit-under-test 100, respectively, to obtain the detection voltage V1, and to obtain correspondingly the first boundary value and the second boundary value. The detection voltage is then a voltage value related to the resistor of the unit-under-test 100, and the reference voltage Vref is a voltage value related to the resistance reference value RT. By comparing the two (the detection voltage and the reference voltage Vref) and performing calculation, the range of the resistance of the unit-under-test 100 may be obtained. The obtained resistance value is greater than the minimum resistance value Rmin and less than the maximum resistance value Rmax, i.e., within the range of {Rmin, Rmax}. If the obtained resistance value does not fall in this range, the test current is not selected appropriately and the value to be compared needs to be reset.

In another embodiment, the test voltage V1 is a reference value, and the reference voltage Vref is the value to be compared. That is, the test voltage V1 is a fixed value. For example, the test current supply unit 210 applies a set current reference value I1n to the resistance of the unit-under-test 100, and obtains a fixed test voltage V1n as the reference value. The reference voltage supply circuit obtains the lower limit value and the upper limit value of the reference voltage Vref according to the preset minimum resistance value Rmin and the maximum resistance value Rmax, respectively, and uses the lower limit value and the upper limit value of the reference voltage Vref as the first boundary value and the second boundary value, respectively. By comparing the two (i.e., comparing the lower limit value and the upper limit value of the reference voltage Vref with V1n), the range of the resistance of the unit-under-test 100 may be obtained after conversion. The obtained resistance value should be within the range formed by the minimum resistance value Rmin and the maximum resistance value Rmax. If the obtained resistance value does not fall within the range, the reference voltage Vref is not properly selected, and the value to be compared needs to be reset.

Furthermore, after determining the upper limit and lower limit of the value to be compared, the range between the two values to be compared may be continuously narrowed through step adjustment, thereby continuously obtaining a resistance range with a higher accuracy. That is, the resistance control unit 240 may also adjust the first boundary value and the second boundary value stepwise based on the first comparison result, the second comparison result, and a detection accuracy, to update the detected resistance range until the resistance range reaches the detection accuracy. In each step adjustment, the range of values bounded by the first boundary value and the second boundary value is narrowed, such that the measured resistance value continuously approaches the true resistance value. For the two examples provided above, the resistance control unit 240 adjusts the first boundary value and the second boundary value by adjusting the test current generated by the test current supply unit 210, or by adjusting the voltage value generated by the reference voltage supply circuit. The comparison unit 230 performs multiple comparisons and outputs comparison results, and the resistance control unit 240 obtains the resistance range multiple times, thereby continuously improving the accuracy of the detected resistance value and the accuracy of resistance detection.

FIG. 3 is a schematic flowchart of a resistance detection method according to an embodiment of the present disclosure. As shown in FIG. 3, the resistance detection method includes steps S101-S104, as follows:

In step S101, the test voltage and the reference voltage are acquired, one of which is set as a value to be compared, and the other one is set as a reference value with a fixed value. The value to be compared includes a first boundary value and a second boundary value. In this step, the test voltage V1 is a voltage value obtained by applying a test current to the unit-under-test 100, and the reference voltage Vref is a voltage value generated by the reference voltage supply circuit.

Specifically, when the test voltage V1 is the value to be compared and the reference voltage Vref is the reference value, this step includes: setting the minimum resistance value Rmin and the maximum resistance value Rmax, and obtaining an upper limit value and a lower limit value of the test current based on the minimum resistance value and the maximum resistance value, respectively; applying the upper limit value of the test current and the lower limit value of the test current to the resistor of the unit-under-test 100, respectively, to obtain correspondingly the first boundary value V1up and the second boundary value V1dn; and setting the resistance reference value RT, and obtaining the fixed reference voltage Vref as the reference value based on the resistance reference value RT. When the test voltage V1 is the reference value and the reference voltage Vref is the value to be compared, this step includes: setting the minimum resistance value Rmin and the maximum resistance value Rmax, obtaining the lower limit value Vref1 and the upper limit value Vref2 of the reference voltage based on the minimum resistance value and the maximum resistance value, respectively, and using the lower limit value Vref1 and the upper limit value Vref2 as the first boundary value and the second boundary value, respectively; and applying the set current reference value I1n to the resistor of the unit-under-test 100 to obtain a fixed test voltage V1n as the reference value.

In step S102, the first boundary value and the second boundary value are compared with the reference value respectively to obtain the first comparison result and the second comparison result.

In step S103, the resistance range of the unit-under-test is calculated based on the first comparison result and the second comparison result. Both the first comparison result and the second comparison result are inequalities relating to the resistor R of the unit-under-test 100, thus allowing to obtain the range of values that R may take. If the resistance range calculated based on the first comparison result and the second comparison result does not fall within the resistance range (Rmin, Rmax) formed by the minimum resistance value and the maximum resistance value, then the value to be compared needs to be reset. When the unit-under-test 100 is a PD, the measured resistance is not considered as conforming to the protocol standard.

In step S104, the first boundary value and the second boundary value are adjusted based on the first comparison result, the second comparison result, and the detection accuracy. After this step, the process returns to step S102 and repeats continuously until a suitable resistance range is detected. That is, the first boundary value and the second boundary value are continuously adjusted step by step based on the first comparison result, the second comparison result, and the detection accuracy to update the resistance range until the resistance range reaches the detection accuracy. Each step adjustment of the first boundary value and the second boundary value will reduce the range of values bounded by the first boundary value and the second boundary value. That is, the first boundary value and the second boundary value are adjusted by adjusting the test current applied to the unit-under-test 100, or by adjusting the voltage value generated by the reference voltage supply circuit.

Specifically, when the test voltage is the value to be compared and the reference voltage Vref is the reference value, this step includes: if each time the first comparison result is that the first boundary value is greater than the reference value (V1up>Vref), then the upper limit of the test current is decreased by a step until the first boundary value is less than the reference value; if each time the second comparison result is that the second boundary value is less than the reference value (V1dn<Vref), then the lower limit of the test current is increased by a step until the second boundary value is greater than the reference value; if the resistance range obtained from the first comparison result and the second comparison result reaches the detection accuracy, then the adjustment of the first boundary value and the second boundary value is stopped. That is, the step adjustment process may be stopped when the resistance range reaches the detection accuracy, or if the resistance range is always within the accuracy range, then wait until the comparison conditions mentioned above are met.

When the test voltage V1 is the reference value and the reference voltage is the value to be compared, this step includes: if each time the first comparison result is that the first boundary value is less than the reference value (Vref1<V1), then the lower limit of the reference voltage is increased by a step until the first boundary value is greater than the reference value; if each time the second comparison result is that the second boundary value is greater than the reference value (Vref2>V1), then the upper limit of the reference voltage is decreased by a step until the second boundary value is less than the reference value; if the resistance range obtained according to the first comparison result and the second comparison result reaches the detection accuracy, then the adjustment of the first boundary value and the second boundary value is stopped. This example is similar to the step adjustment process of the previous embodiment, and will not be repeated again here.

When the unit-under-test 100 is a powered device, if the resistance value is within the resistance range specified in the protocol, it is determined that the impedance of the powered device meets the protocol standard. If the resistance value does not fall entirely within the resistance range specified in the protocol, it is determined that the impedance of the powered device does not meet the protocol standard. Herein, determining that the resistance range falls within the resistance range specified in the protocol means that the measured resistance range falls entirely within the resistance range specified in the protocol.

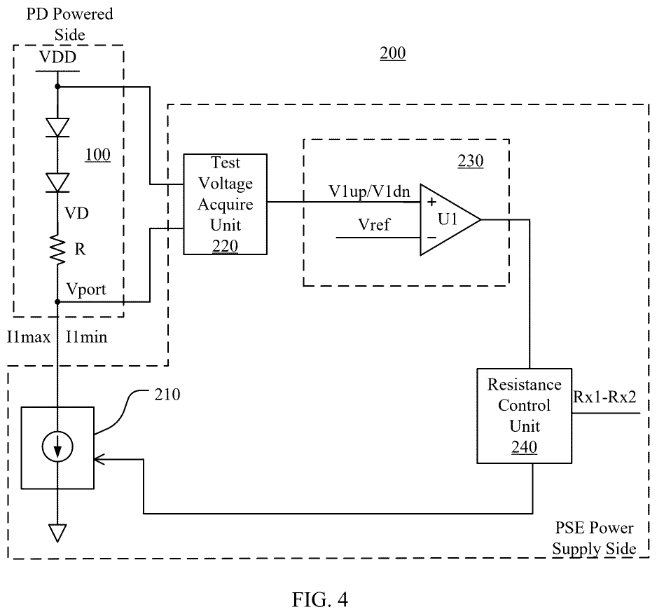

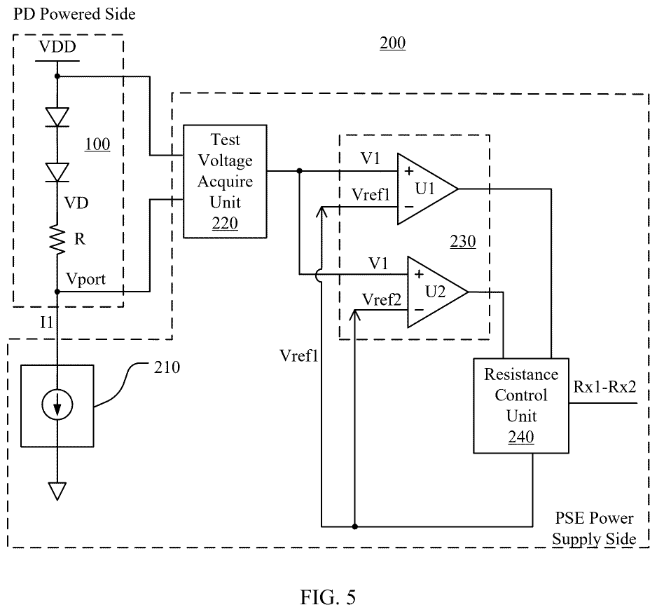

The following examples illustrate, using example circuit diagrams in FIG. 4 and FIG. 5, scenarios where the test voltage is used as the value to be compared and where the reference voltage is used as the value to be compared.

FIG. 4 is a schematic circuit diagram of a resistance detection circuit 200 according to a first embodiment of the present disclosure. The unit-under-test 100 herein is a PD device as an example, that is, the impedance of the PD at the PD powered side is detected. The PD is simplified as a circuit formed by two diodes and a resistor connected in series, with a characteristic resistance of R. Then, the voltage difference across its powered terminals is V1=VD+I1×R, where VD is the voltage drop across the two diodes. The test current supply unit 210 may include a current source, and the comparison unit 230 may include one or two comparators, for example, only including a comparator U1, or including both the comparator U1 and a comparator U2. The comparison unit 230 herein includes only the comparator U1 as an example, in which case, the comparator U1 is used in a time-division multiplexing manner when determining the resistance range each time. Since the characteristic resistance limit specified by the POE protocol is a resistance range, this embodiment is configured to detect correspondingly a resistance range Rx1-Rx2. That is, by applying different currents I1 to the PD powered terminals, different voltage drops V1 are generated, which are compared with the reference voltage Vref, and the resistance range may be determined by the output of the comparison unit 230.

As shown in FIG. 4, with the resistance reference value represented by RT, the fixed reference voltage may be set as Vref=VD+I0×RT, where I0 is a fixed test current value. However, the value taken for I0 needs to ensure that the reference voltage Vref is less than an upper limit of the detection voltage range (e.g., 0-10V) specified in the protocol. Preferably, Vref may take a middle value of the detection voltage range, for example, by setting I0 such that Vref=5V. Then, according to the principle of a comparator, when Vref>V1, R<I0×RT/I1, and conversely, when Vref<V1, R>I0×RT/I1. When taking the two boundary values of a large value range as the test voltages, and compared the test voltages with the reference voltage, R may be controlled to be within a certain range, that is, R may be greater than one value and less than another value. At this time, the comparator U1 receives the two boundary values in a time-division multiplexing manner, and then compares them with the same reference value. The two comparison results of the comparator U1 are input to the resistance control unit 240. The resistance control unit 240 may obtain a resistance range through an algorithm, thereby adjusting the current change of the test current supply unit 210.

In this embodiment, during first two tests, two boundary values for the test current may first be set, i.e., I1max=I0×RT/Rmin and I1min=I0×RT/Rmax, from which two test voltage values V1up and V1dn may be obtained correspondingly. Generally, V1up>Vref, and V1dn<Vref. V1up and V1dn are input to the comparator U1 in a time-division multiplexing manner and compared with Vref, respectively. Based on the two comparison results, a resistance range may be obtained. The minimum resistance value Rmin and the maximum resistance value Rmax may be the minimum and maximum characteristic impedances desired by the PSE power supply side, respectively, and may also be values set according to user requirements. With I1max as the upper limit of the current, the corresponding test voltage V1up obtained is the first boundary value, and with I1min as the lower limit of the current, the corresponding test voltage V1dn obtained is the second boundary value. After calculation, R should be within the range of (Rmin, Rmax). If detecting, based on the result of the comparator, that R is less than Rmin or greater than Rmax, it may be directly determined that the impedance of the powered side does not meet the protocol standard.

If R is within the range of (Rmin, Rmax), in subsequent tests, I1max and I1min may be adjusted according to the current step that is set based on the resistance detection accuracy, to continuously narrow the range between I1max and I1min. That is, the step value is set according to the resistance detection accuracy, and then I1max is decreased and I1min is increased accordingly. Thereafter, the resistance range is updated continuously according to the comparison results of the detection voltages V1up and V1dn with the reference voltage Vref. When I1max decreases, if V1up>Vref still holds, i.e., R>I0×RT/I1max holds, I1max may be decreased again. I1max may be continuously decreased by steps until V1up<Vref, i.e., R<I0×RT/I1max. At this time, stop decreasing I1max, and the maximum lower limit of R may be measured. Furthermore, a similar determination may be made when increasing I1min according to the detection accuracy step. That is, after increasing the detection current, V1dn<Vref still holds, i.e., R<I0×RT/I1min, then I1min may continue to be increased in the next test until V1dn>Vref, i.e., R>I0×RT/I1min. At this point, stop increasing I1min, and the minimum upper limit of R may be obtained. Finally, when both I1max and I1min stop changing, then I0×RT/I1max<R<I0×RT/I1min. This gives the resistance range of R. If the range of (I0×RT/I1max, I0×RT/I1min) falls entirely within the resistance range specified in the protocol, then the PD meets the protocol requirements.

FIG. 5 is a schematic circuit diagram of a resistance detection circuit 200 according to a second embodiment of the present disclosure.

Similar to FIG. 4, the resistance detection circuit 200 of FIG. 5 includes a test current supply unit 210, a test voltage acquire unit 220, a comparison unit 230, and a resistance control unit 240. In this embodiment, the comparison unit 230 includes two comparators, namely comparator U1 and comparator U2, as an example. As shown in FIG. 5, a fixed voltage drop V1=VD+I1×R is generated by applying a fixed current I1 to the PD powered terminals, which is used as a fixed test voltage V1, i.e., a fixed reference value. The test voltage V1 is then compared with different reference voltages Vref, and the resistance range is determined by the outputs of the comparators. Similar to the settings in FIG. 4, the voltage drop across the two diodes is VD, the characteristic resistance is R, and the resistance reference value is RT. Then the reference voltage may be set as: Vref=VD+I1×Rref. When Vref>V1, R<Rref, and when Vref<V1, R>Rref. The results of the comparators are input to the resistance control unit 240, which determines the change of Vref through an algorithm.

Specifically, during first two tests, Vref1=VD+I1×Rrefmin and Vref2=VD+I1×Rrefmax are set, in order to limit R within the range of (Rrefmin, Rrefmax). Rrefmin and Rrefmax are the minimum and maximum characteristic impedances desired by the PSE power supply side, which may be equivalent to Rmin and Rmax mentioned above, i.e., the two boundary values obtained based on the minimum and maximum resistance values. If R measured after the comparison of the comparators is less than Rrefmin or greater than Rrefmax, it may be directly determined that the powered side does not conform to the protocol. If R is indeed within the range of (Rrefmin, Rrefmax), in subsequent tests, Vref1 and Vref2 may be adjusted according to the current step that is set based on the resistance detection accuracy, such that the value range between them is continuously narrowed. That is, a step value is set according to the resistance detection accuracy, and then Vref2 is decreased and Vref1 is increased accordingly. The resistance range is then updated based on the comparison results of the detection voltage V1 with Vref1 and Vref2, respectively. Since Vref1=VD+I1×Rrefmin and Vref2=VD+I1×Rrefmax, and VD and I1 are fixed values, this actually adjusts the values of Rrefmin and Rrefmax in steps to adjust Vref1 and Vref2 in steps. Furthermore, in this embodiment, the reference voltage generation circuit may be provided inside the resistance control unit 240, to facilitate the control of the reference voltage.

During the adjustment process, when Vref1 increases, if Vref1<V1 (i.e., R>Rref1), then Vref1 may continue to be increased until Vref1>V1 (i.e., R<Rref1), at which point, increasing Vref1 may be stopped. Similarly, when Vref2 decreases, if Vref2>V1 (i.e., R<Rref2), then Vref2 may continue to be decreased until Vref2<V1 (i.e., R>Rref2), at which point, decreasing Vref2 may be stopped. Finally, when both Vref1 and Vref2 stop changing, Rref2<R<Rref1. If (Rref2, Rref1) is within the resistance range specified in the protocol, then the powered device meets the protocol requirements. This completes the detection of the resistance value of the unit-under-test 100, with an accuracy within a very small range. The circuit structure is simple, the calculation accuracy is high, the circuit occupation area is small, and the cost is low.

The embodiment resistance detection methods and circuits obtain the resistance range of the unit-under-test based on boundary values and reference values provided by a low-voltage circuit, improve the accuracy of resistance detection, reduce the use of high-voltage devices, reduce the circuit area occupied, and reduce costs.

The embodiments may be applied to various applications where a resistance of an electronic device is to be measured. For example, a current may be applied to the electronic device to generate a voltage across the electronic device, and a reference voltage may be generated depending on the application of the electronic device. As described above, one of the voltage across the electronic device and the reference voltage may be set as a value-to-be-compared (or a parameter-to-be compared, where the parameter is a voltage), and the other one of the voltage across the electronic device and the reference voltage may be set as a reference. Two boundary values may be generated for the parameter-to-be compared and compared with the reference to generate respective comparison results, based on which a range of the resistance of the electronic device may be determined according to the relationship between resistance, current and voltage. The two boundary values are two voltage values generated based on a minimum resistance and a maximum resistance preset for the electronic device.

It should be noted that the numerical values in this disclosure are for illustrative purposes only. In other embodiments of the present disclosure, other numerical values may be used to implement the solution. The specific values may be reasonably set according to the actual situations, and the present disclosure does not limit them.

Finally, it should be noted that the above embodiments are merely examples for clearly illustrating the present disclosure and are not intended to limit the implementations. Those ordinarily skilled in the art would recognize that other variations or modifications can be made based on the above description. It is neither necessary nor possible to exhaustively list all possible implementations. However, obvious variations or modifications derived therefrom are still within the protection scope of this disclosure.

It should also be understood that the terminology and expressions used in this disclosure are for descriptive purposes only. One or more embodiments of the present disclosure are not limited to the terminology and expressions. The use of the terminology and expressions does not exclude any equivalent features in illustration and description (or parts thereof), and it should be recognized that various modifications that may exist should also be included within the scope of the claims. Other modifications, variations, and substitutions may also exist. Accordingly, the claims should be considered to cover all such equivalents.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, which may perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed:

1. A resistance detection method for detecting a resistance of a unit-under-test, comprising:
obtaining a test voltage and a reference voltage, with one of the test voltage and the reference voltage set as a value-to-be-compared, and the other one set as a reference value with a fixed value, wherein the value-to-be-compared includes a first boundary value and a second boundary value;
comparing the first boundary value and the second boundary value with the reference value, respectively, to obtain a first comparison result and a second comparison result; and
determining a resistance range to which the resistance of the unit-under-test belongs based on the first comparison result and the second comparison result;
wherein the test voltage is a value obtained by applying a test current to the unit-under-test, and the reference voltage is a value generated by a reference voltage supply circuit.

2. The resistance detection method of claim 1, wherein the test voltage is the value-to-be-compared, the reference voltage is the reference value, and obtaining the test voltage and the reference voltage comprises:
setting a minimum resistance and a maximum resistance, and obtaining an upper limit value and a lower limit value of the test current based on the minimum resistance and the maximum resistance, respectively;
applying the test current taking the upper limit value and the lower limit value respectively to a resistor of the unit-under-test, to obtain the first boundary value and the second boundary value; and
setting a resistance reference value, and obtaining the reference voltage with a fixed value based on the resistance reference value as the reference value.

3. The resistance detection method of claim 2, further comprising:
resetting the value-to-be-compared when the resistance range determined based on the first comparison result and the second comparison result does not belong to a resistance range formed by the minimum resistance and the maximum resistance.

4. The resistance detection method of claim 2, further comprising:
adjusting stepwise the first boundary value and the second boundary value based on the first comparison result, the second comparison result and a detection accuracy, to update the resistance range until the resistance range reaches the detection accuracy, wherein the first boundary value and the second boundary value are adjusted stepwise each time such that a range bounded by the first boundary value and the second boundary value decreases.

5. The resistance detection method of claim 4, wherein adjusting the first boundary value and the second boundary value comprises:
adjusting the test current applied to the unit-under-test to adjust the first boundary value and the second boundary value, or
adjusting the reference voltage generated by the reference voltage supply circuit to adjust the first boundary value and the second boundary value.

6. The resistance detection method of claim 4, wherein adjusting stepwise the first boundary value and the second boundary value comprises:
when the first comparison result each time is that the first boundary value is greater than the reference value, decreasing the upper limit value of the test current stepwise until the first boundary value is less than the reference value;
when the second comparison result each time is that the second boundary value is less than the reference value, increasing the lower limit value of the test current stepwise until the second boundary value is greater than the reference value; and
when the resistance range obtained based on the first comparison result and the second comparison result reaches the detection accuracy, stopping adjusting the first boundary value and the second boundary value.

7. The resistance detection method of claim 1, wherein the test voltage is the reference value, the reference voltage is the value-to-be-compared, and obtaining the test voltage and the reference voltage includes:
setting a minimum resistance and a maximum resistance, and obtaining a lower limit value and an upper limit value of the reference voltage based on the minimum resistance and the maximum resistance, respectively, with the lower limit value and the upper limit value of the reference voltage set as the first boundary value and the second boundary value, respectively;
applying a current with a current reference value to a resistor of the unit-under-test, to obtain the test voltage with a fixed value as the reference value.

8. The resistance detection method of claim 7, further comprising:
resetting the value-to-be-compared when the resistance range determined based on the first comparison result and the second comparison result does not belong to a resistance range formed by the minimum resistance and the maximum resistance.

9. The resistance detection method of claim 7, further comprising:
adjusting stepwise the first boundary value and the second boundary value based on the first comparison result, the second comparison result, and a detection accuracy, to update the resistance range until the resistance range reaches the detection accuracy, wherein each time the first boundary value and the second boundary value are adjusted by the detection accuracy step such that a range bounded by the first boundary value and the second boundary value decreases.

10. The resistance detection method of claim 9, wherein adjusting the first boundary value and the second boundary value comprises:
adjusting the test current applied to the unit-under-test to adjust the first boundary value and the second boundary value, or
adjusting the reference voltage generated by the reference voltage supply circuit to adjust the first boundary value and the second boundary value.

11. The resistance detection method of claim 9, wherein adjusting stepwise the first boundary value and the second boundary value comprise:
when the first comparison result each time is that the first boundary value is less than the reference value, increasing the lower limit value of the reference voltage stepwise until the first boundary value is greater than the reference value;
when the second comparison result each time is that the second boundary value is greater than the reference value, decreasing the upper limit value of the reference voltage stepwise until the second boundary value is less than the reference value; and
when the resistance range obtained based on the first comparison result and the second comparison result reaches the detection accuracy, stopping adjusting the first boundary value and the second boundary value.

12. The resistance detection method of claim 1, wherein the unit-under-test is a powered device, and the resistance detection method further comprises:
when the resistance range is within a protocol specified resistance range, determining that impedance of the powered device satisfies a protocol standard.

13. A resistance detection circuit, connected to a unit-under-test, for detecting a resistance of the unit-under-test, the resistance detection circuit comprising:
a test current supply unit configured to apply a test current to the unit-under-test to generate a test voltage;
a test voltage acquire unit configured to acquire the test voltage from two terminals of the unit-under-test;
a comparison unit configured to: obtain a reference voltage generated by a reference voltage supply circuit, set one of the test voltage and the reference voltage as a value-to-be-compared, and the other one as a reference value with a fixed value, the value-to-be-compared including a first boundary value and a second boundary value, and compare the first boundary value and the second boundary value with the reference value respectively to obtain a first comparison result and a second comparison result; and
a resistance control unit configured to calculate a resistance range to which the resistance of the unit-under-test belongs based on the first comparison result and the second comparison result.

14. The resistance detection circuit of claim 13, wherein the resistance control unit is further configured to adjust stepwise the first boundary value and the second boundary value based on the first comparison result, the second comparison result and a detection accuracy, to update the resistance range until the resistance range reaches the detection accuracy, wherein the first boundary value and the second boundary value are adjusted stepwise each time such that a range bounded by the first boundary value and the second boundary value decreases.

15. The resistance detection circuit of claim 14, wherein the resistance control unit is further configured to:
adjust the first boundary value and the second boundary value by adjusting the test current generated by the test current supply unit, or
adjust the first boundary value and the second boundary value by adjusting the reference voltage generated by the reference voltage supply circuit.

16. The resistance detection circuit of claim 13, wherein the test voltage is the value-to-be-compared, and the reference voltage is the reference value;
the test current supply unit is further configured to obtain an upper limit value and a lower limit value of the test current according to a minimum resistance and a maximum resistance preset, respectively, and apply the test current taking the upper limit value and the lower limit value respectively to a resistor of the unit-under-test, to obtain the first boundary value and the second boundary value; and
the reference voltage supply circuit is further configured to obtain the reference voltage with a fixed value based on a preset resistance reference value as the reference value.

17. The resistance detection circuit of claim 13, wherein the test voltage is the reference value, and the reference voltage is the value-to-be-compared;
the reference voltage supply circuit is further configured to obtain a lower limit value and an upper limit value of the reference voltage according to preset minimum resistance and the maximum resistance, respectively, and set the lower limit value and the upper limit value of the reference voltage as the first boundary value and the second boundary value, respectively; and
the test current supply unit is further configured to apply a current having a set current reference value to a resistor of the unit-under-test, and obtain the test voltage with a fixed value as the reference value.

18. The resistance detection circuit of claim 13, wherein the comparison unit includes at least one comparator, and when the comparison unit includes only a comparator, the comparator is configured receives the first boundary value and the second boundary value in a time-division multiplexing manner.

19. A method comprising:
applying a current to a powered device to generate a voltage across the powered device;
selecting one of the voltage and a reference voltage as a parameter-to-be-compared, and the other one as a reference with a fixed value, the parameter-to-be-compared having a first boundary value and a second boundary value;
comparing the first boundary value and the second boundary value of the parameter-to-be-compared with the reference, to generate a first comparison result and a second comparison result; and
detecting a range of a resistance of the powered device based on the first comparison result and a second comparison result.

20. The method of claim 19, further comprising:
generating the first boundary value and the second boundary value based on a minimum resistance and a maximum resistance preset for the powered device; and
generating the reference voltage based on a preset resistance reference.
